(19) United States
(12) Patent Application Publication
(10) Pub. No.: US 2007/0226567 A1
(43) Pub. Date: Sep. 27, 2007

(54) HIGH SPEED BIST UTILIZING CLOCK MULTIPLICATION

(76) Inventors: Kevin W. Gorman, Fairfax, VT (US); Gerald P. Pomichter JR., Fairfax, VT (US)

Correspondence Address: HOFFMAN, WARNICK & D'ALESSANDRO LLC, 75 STATE ST, 14TH FLOOR, ALBANY, NY, 12207, US

(21) Appl. No.: 11/277,310

(22) Filed: Mar. 23, 2006

(51) Int. Cl. G01R 31/28

(52) U.S. Cl. 714/733

(57) ABSTRACT

A system and method of performing high speed built-in self test (BIST) using clock multiplication. A system is provided for testing a high speed integrated circuit using a low speed tester, comprising: a built-in self test (BIST) engine coupled to the integrated circuit; a clock multiplier adapted to derive a high speed clock signal from a clock signal supplied by the low speed tester, wherein the high speed clock signal drives the testing of the high speed integrated circuit; and an edge shaper coupled to the clock multiplier and the BIST engine, the edge shaper configured to output a plurality of different shaped clock signals.

### FIELD OF THE INVENTION

The invention relates generally to testing application specific integrated circuit (ASIC) devices, and more particularly relates to a high speed BIST (built-in self-test) system and method for testing memory on an ASIC device.

### BACKGROUND OF THE INVENTION

The design and manufacture of integrated circuits that are free of design and reliability problems is a challenging task. Accordingly, it is standard practice to test integrated circuits for functional failures, as well as for propensities to reliability problems. Such device testing is critical for identifying, analyzing, and correcting problem areas early.

One of the important areas in which tests must be performed involves random access memory (RAM), and more specifically dynamic random access memory (DRAM) in which testing involves the writing and reading of data from each bit in the memory. Moreover, during testing, it is important that the reading and writing of data be done at the speed at which the DRAM will ultimately attain in functional mode. However, such testing is particularly challenging in an ASIC device in which typical testers are designed to run at speeds much slower than the operational speed of the DRAM. Because stand-alone testers alone are not practical to use for the testing of DRAMs in an ASIC device, performing full coverage testing of the DRAM remains a challenge.

Proposed solutions typically involve “through the pad” testing, which utilize a much more sophisticated tester capable of much higher frequencies. Unfortunately, such solutions are much more costly and require many more pins on the ASIC device to provide full test coverage by the tester. It has also been proposed to multiply tester clocks to achieve higher frequencies. However, none of the prior art describes a system whereby a BIST engine with a re-programmable memory can dynamically control the multiplier and/or shaper affects on the tester clock; perform a modifiable, test pattern sensitive, accuracy check on the multiplied and/or shaped tester clock; and/or perform memory test patterns that provide pattern based noise immunity to increase the accuracy of the multiplied and/or shaped tester clock. Accordingly, a need exists for a system and method that will allow for at speed testing of a DRAM in an ASIC device.

### SUMMARY OF THE INVENTION

The present invention addresses the above-mentioned problems, as well as others, by providing a high speed clock multiplier and a memory BIST in a single, high speed test solution. The solution, e.g., allows an embedded DRAM to be clocked by a BIST at frequencies greater than 500 MHz with a supplied tester clock frequency of between 25 and 125 MHz. In order to achieve these frequencies and produce a pattern based test sequence running at such frequencies, a dedicated clock multiplier and clock shaper is used to drive a reprogrammable BIST with dedicated high speed functionality. The reprogrammable nature of the BIST provides support for a high speed multiplied clock-based test system. This system allows for dynamically controlling the multiplier/shaper settings, testing the accuracy of the generated clocks, and running patterns that provide noise immunity.

In a first aspect, the invention provides a system for testing a high speed integrated circuit using a low speed tester, comprising: a built-in self test (BIST) engine coupled to the integrated circuit; a clock multiplier adapted to derive a high speed clock signal from a clock signal supplied by the low speed tester, wherein the high speed clock signal drives the testing of the high speed integrated circuit; and an edge shaper coupled to the clock multiplier and the BIST engine, the edge shaper configured to output a plurality of different shaped clock signals.

In a second aspect, the invention provides an application specific integrated circuit (ASIC) device having a system for testing a high speed memory circuit using a low speed tester, the ASIC device comprising: a built-in self test (BIST) engine; a clock multiplier adapted to derive a high speed clock signal from a clock signal supplied by the low speed tester, wherein the high speed clock signal drives the testing of the high speed memory circuit; and an edge shaper coupled to the clock multiplier and the BIST engine, the edge shaper configured to output a plurality of different shaped clock signals.

In a third aspect, the invention provides a method of testing a high speed memory circuit in an application specific integrated circuit (ASIC) device using a low speed clock, comprising: providing a built-in self test (BIST) engine in the ASIC device; providing a clock multiplier in the ASIC device; providing an edge shaper in the ASIC device coupled to the clock multiplier and the BIST engine; loading a multiplier factor from the BIST engine to the clock multiplier; enabling the clock multiplier with an enable signal from the BIST engine to cause a high speed clock signal to be generated; allowing a period of time to pass to allow the high speed clock signal to lock into a steady state; and testing the high speed memory circuit with the high speed clock.

As described herein, a system and method are provided for testing a DRAM in which there is no on-board high speed clock generation requirements (e.g., using a phase lock loop, delay lock loop, etc.). In addition, the solution provides for programmable clock multiplication and division/shaping controlled by a BIST engine with a re-programmable memory. Also provided are modifiable BIST clock multiplier startup and shutdown sequencing, modifiable BIST support to test clock multiplication accuracy, and modifiable pattern support to address noise induced multiplied clock accuracy problems.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts high frequency test system for testing a DRAM in an ASIC device in accordance with an embodiment of the present invention.

FIG. 2 depicts an example of a low frequency clock signal and two high frequency clock signals in accordance with an embodiment of the present invention.

FIG. 3 depicts a timing diagram of a start-up sequence of a clock multiplier in accordance with an embodiment of the present invention.

FIG. 4 depicts a flow diagram of a start-up and shut-down sequence of a clock multiplier in accordance with an embodiment of the present invention.

FIG. 5 depicts a flow diagram of a shaper start-up and shut-down sequence in accordance with an embodiment of the present invention.

FIG. 6 depicts a flow diagram of multiplier test process in accordance with an embodiment of the present invention.

### DETAILED DESCRIPTION

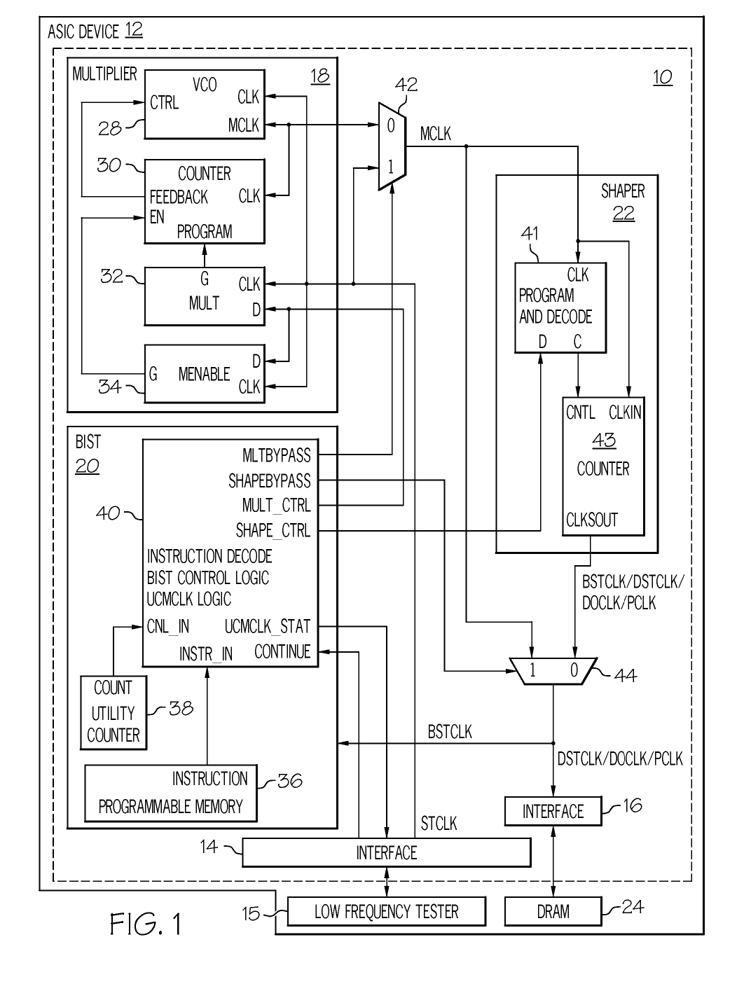

Referring now to drawings, FIG. 1 depicts an illustrative embodiment of a high frequency test system 10 for testing a DRAM 24 in an ASIC device 12. Note that the illustrative embodiment shown in FIG. 1 is referred to throughout this disclosure in conjunction with the other figures. High frequency test system 10 includes a clock multiplier (“multiplier”) 18, a BIST engine (“BIST”) 20, an edge shaper (“shaper”) 22, a first interface 14 to a low frequency tester 15, and a second interface 16 to DRAM 24. High frequency test system 10 allows for high frequency testing of DRAM 24 using a low frequency input clock (referred to here in as “input clock” or STCLK) supplied by low frequency tester 15. It should be recognized that while the illustrative embodiments described herein are generally directed to the testing of a DRAM 24 in an ASIC device 12, the invention could be utilized in the testing of any integrated circuit device.

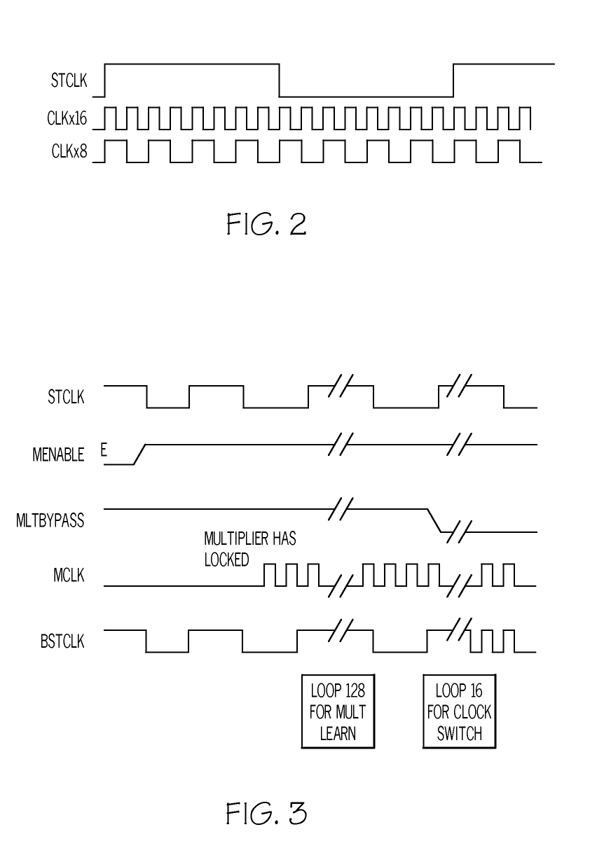

Multiplier 18 utilizes a voltage controlled oscillator (VCO) 28 with a phase/frequency detector to produce high speed clocks (MCLK) that are fed to shaper 22, DRAM 24, and/or BIST 20. Each clock, which is counted by a counter 30, comprises a set of clock pulses that are in phase with the input clock (STCLK) and are at an integer multiple of the input clock frequency. FIG. 2 depicts an example of an input clock (STCLK) and two possible multiplied clocks CLKx16 and CLKx8, generated by multiplier 18.

The multiplication factor of the input clock is determined by a multiplier factor stored in a MULT register 32. Also included is a control latch (MENABLE) 34, which provides an enable/disable control bit. MULT register 32 and control latch (MENABLE) 34 can be loaded with a dedicated instruction from BIST logic 40. This instruction is the result of a defined pattern word stored in the BIST programmable memory 36 that is interpreted by BIST logic 40. The multiplier logic sits in steady state until BIST logic 40 enables MENABLE by setting its value to 1 and returns to steady state following a disable, i.e., MENABLE set to 0, command from BIST logic 40.

Multiplier 18 requires a predictable amount of time in order for the generated high frequency clock to “lock,” i.e., to achieve a steady state of the required frequency and phase. The amount of time required until locking occurs is factored into the BIST programming by BIST logic 40, such that no critical functions are being initiated during the initial lock period. BIST logic 40 can, for example, be programmed to issue a number of non-operational (NOOP) cycles or it can be programmed to wait for a CONTINUE signal from tester 15 to begin running a valid pattern.

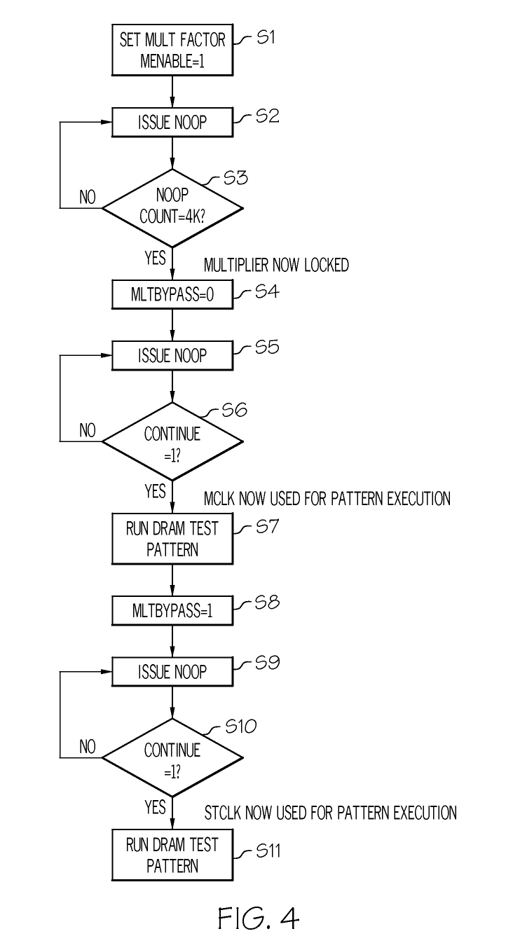

The start-up and shut-down control processes for multiplier 18 are shown in further detail in FIGS. 3 and 4. FIG. 3 depicts a timing diagram showing a start-up sequence in which STCLK shows the input clock and the MCLK signal shows the multiplied clock generated by multiplier 18. Multiplier 18 is controlled by setting latches via a dedicated command much like the commands used to set other test modes in a DRAM test. The command is issued via the BIST programmable memory 36 and is used to set values for the MULT register 32 and MENABLE latch 34. BIST logic 40 first enables the multiplier by setting MENABLE to ‘1’ as shown in FIG. 3, and then waits to allow the multiplier 18 to lock, e.g., by looping on a branch instruction for a few startup cycles (e.g., while issuing NOOP cycles). The number of startup cycles required is dictated by the multiplier design and programming conditions. Once the multiplier 18 is locked, BIST logic 40 can issue a multiplier start clock command to multiplexer (mux) 42 by setting MLTBYPASS to 0 to allow the internal clocks to switch from running off the input clock (STCLK) to the internal multiplied clock (MCLK).

To switch back to the input clock (STCLK), BIST logic 40 simply issues a multiplier stop clock command by setting MLTBYPASS to 1. All clock start/clock stop commands should be followed by a loop until a CONTINUE signal is asserted for a predetermined number of STCLK cycles (e.g., 16 NOOP cycles) to allow the clock domain switch to complete before executing new instructions.

FIG. 4 is a flow diagram that illustrates the steps involved in the start-up and shut-down sequences. All actions described therein are controlled by BIST 20. At step S1, the start-up process is initiated by setting a multiplication factor in the MULT register 32 and setting MENABLE to 1. At steps S2 and S3, some predetermined number (e.g., four thousand) of NOOPs is issued to lock the multiplier 18. At step S4, MLTBYPASS is set to 0 to switch from the input clock to the multiplied clock. At steps S5 and S6, the process loops until a CONTINUE signal is pulsed to 1. Waiting for the CONTINUE pulse allows for the clock domain switch to occur. Once the CONTINUE signal is set to 1, the DRAM test pattern is run at step S7 with the multiplied clock (MCLK).

The shut-down sequence begins by setting the MLTBYPASS to 1 at step S8. At steps S9 and S10, the process loops until the CONTINUE signal is again pulsed to 1. Once the CONTINUE signal is pulsed to 1, the DRAM test pattern is run at step S11 with the input clock (STCLK).

Multiplier 18 will continuously learn (adjust to changing conditions/clock cycles) while it is in use. If tester 15 cycles are altered to go either faster or slower (higher or lower frequency), multiplier 18 will “learn” to maintain the proper output frequency. If ASIC 12 environment changes due to either changing temperature or supply voltages, multiplier 18 will “learn” by adjusting VCO 28 using the phased detector included in the VCO 28 in order to adjust to these changing conditions. In either case, changing conditions or an altered tester 15 clock frequency, multiplier 18 will require time to make the adjustment prior to regaining “lock” to the correct frequency. The timing of the learning processes are shown in the timing diagram of FIG. 3 where process is instructed to loop for 128 cycles for clock multiplier learn and loop for 16 cycles for clock switching.

As noted above, a shaper 22 is provided to generate different shaped signals. Examples of different clock shapes provided by shaper 22 may include:

1. BSTCLK—BIST CLK, used for BIST/Test circuit clocking;

2. DSTCLK—DRAM CLK, used for DRAM clocking;

3. PRCH—DRAM Precharge clock, used for timing the DRAM array word-line active time; and

4. DOCLK—DRAM Data Out clock, used for launching data from the DRAM macro.

Each shaped signal is generated by counting cycles using counter 43 (FIG. 1) from the multiplied clock (MCLK) or input clock (STCLK), depending on the MLTBYPASS state. Each signal has a programmed rising and falling point that is governed by the information loaded into a shaper program/decode register 41 by BIST logic 40. The programmed cycle period of each shaped signal is typically the same and is likewise determined by BIST logic 40 and is set in shaper program/decode register 41, which determines the overall clock division value.

Shaper 22 is started by having BIST logic 40 issue a shaper clock start command (i.e., SHAPEBYPASS=0) from BIST programmable memory 36 to mux 44. At that point, all clocks are switched from being generated directly from either the MCLK or STCLK to one of the shaper outputs. To stop shaper 22, BIST logic 40 issues a shaper clock stop command (i.e., SHAPEBYPASS=1) from BIST programmable memory 36 to mux 44. All clocks are then switched from being generated from the shaper outputs back to the MCLK or STCLK.

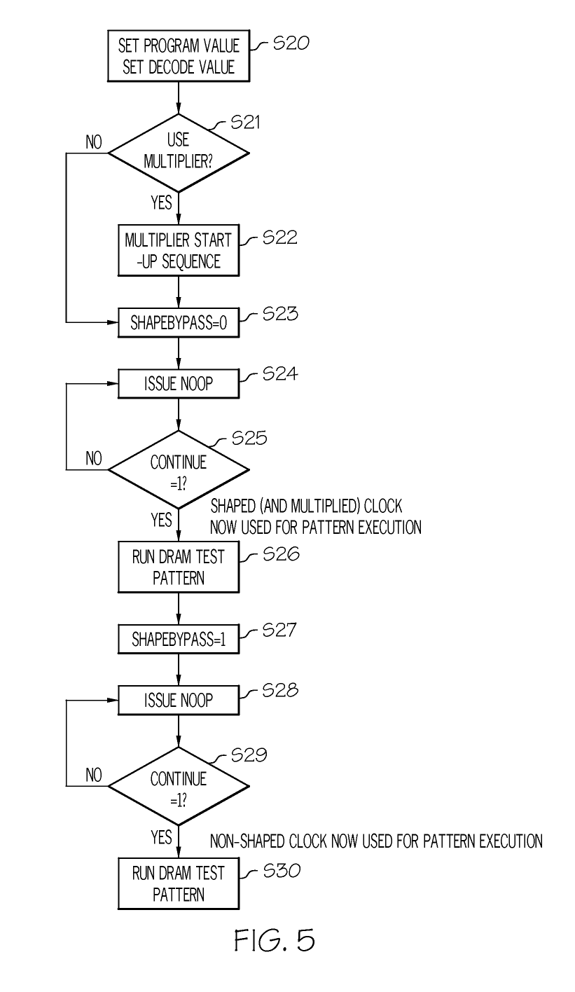

All clock start/stop commands are followed by a loop until a CONTINUE signal is pulsed after a predetermined number of STCLK cycles (e.g., 16 NOOP cycles) to allow the clock domain switch to complete before executing new instructions. FIG. 5 is a flow diagram that illustrates the shaper programming and start-up/shut-down sequence. All methods described in FIG. 5 are controlled by BIST logic 40 (FIG. 1). At step S20, the PROGRAM value and DECODE values are set in shaper program/decode register 42. At steps S21 and S22, a determination is made whether to use multiplier 18. If yes, the multiplier start-up sequence described above is initiated. At step S23, SHAPEBYPASS is set to 0 to turn on shaper 22. At steps S24 and S25, NOOPs are issued until a CONTINUE signal is pulsed to 1, indicating that the shaped clock is ready. At step S26, DRAM test patterns are run with the shaped clock.

At step S27, shaper 22 is turned off by setting SHAPEBYPASS to 1. At steps S28 and S29, NOOPs are issued until a CONTINUE signal is pulsed to 1, indicating that the non-shaped clock is ready. At step S30, DRAM test patterns are run with the non-shaped clock.

Another feature of high frequency test system 10 is the ability to measure the “lock,” or multiplication accuracy using a BIST utility counter 38 (FIG. 1). The BIST utility counter 38, in conjunction with the CONTINUE signal from the low frequency tester 15 via interface 14 can be used to test the accuracy of the multiplier 18. The test defines maximum and minimum utility count values, which establishes a range that the BIST utility counter 38 must reach for a given number of tester clocks. Low frequency tester 15 applies N tester clocks, which generates M*N multiplied clocks (where M is the multiplication factor). After N clocks, BIST utility counter 38 should have decremented about M*N/X times, ± some tolerance (where X is the number of clock cycles the BIST pattern must execute in order for the utility counter to increment). The tester can then assert a CONTINUE signal, which causes a BIST utility counter value to be sampled and compared to the acceptable range. A status bit is set if BIST utility counter 38 is sampled outside the acceptable range, indicating a failing clock multiplier 18.

To perform such a test in the system shown in FIG. 1, a “UCMCLK_TEST” instruction can be issued from BIST programmable memory 36 to accept four arguments: (1) the maximum tolerated utility counter value (UCMCLK_MAX), (2) the minimum tolerated utility counter value (UCMCLK_MIN), (3) an enable signal for activating the test (UCMCLK_EN), and (4) a clear command for resetting the test results (UCMCLK_RESET). The UCMCLK_STAT bit is initialized to a passing (‘0’) value. Every time BIST utility counter 38 is sampled by the CONTINUE signal during an enabled UCMCLK_TEST pass, the status latch updates. If sampling is performed outside of the accepted range, the status latch is set to a ‘1’ and remains set. Once a multiplier test fails, all subsequent multiplier tests will be marked failing unless the UCMCLK_TEST clear command is issued.

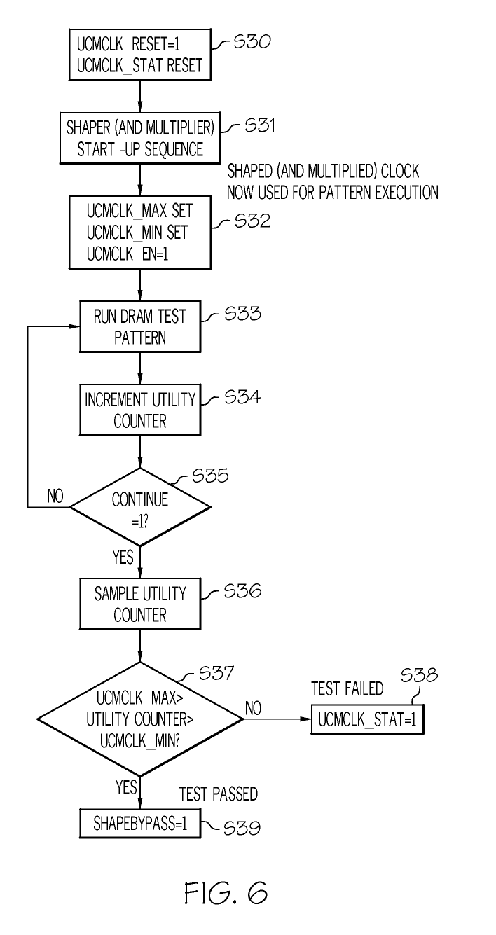

FIG. 6 is a flow diagram that depicts the method used for testing the accuracy of multiplier 18 of FIG. 1. At step S30, UCMCLK_RESET is set to 1 and UCMCLK_STAT is reset. At step S31, the shaper and multiplier start-up sequences are initiated, as required. At step S32, UCMCLK_MAX and UCMCLK_MIN are set, and UCMCLK_EN is set to 1. At steps S33, S34 and S35, DRAM pattern tests are run with the BIST utility counter 38 being incremented periodically until the CONTINUE signal is no longer set to 0. Once the CONTINUE signal is pulsed to 1, BIST utility counter 38 is sampled at step S36.

At step S37, a check is made to see if the value sampled from BIST utility counter 38 is greater than UCMCLK_MAX or less than UCMCLK_MIN. If yes, then UCMCLK_STAT is set to 1 at step S38 indicating that the test failed. If no, then UCMCLK_STAT is set to 0 at step S39 indicating that the test passed.

A further feature of high frequency test system 10 is its ability to provide pattern based noise immunity. The single largest problem confronting the use of a clock multiplier 18 to solve at speed test problems is dealing with the large noise induced frequency/phase shifts. Due to the significant difference between the current drawn for various read, write, and NOOP patterns, the voltage supplies to the multiplier are likely to bounce around with both high frequency and low frequency variations.

In general, the high frequency noise tends to be of lower magnitude and can be solved with a simple RC filter on the supplies. The low frequency, pattern induced noise is generally much more destructive to the supply voltages. In some environments, these supplies can collapse and/or recover by as much as 25-30% due to pattern changes. For example, the following pattern will tend to produce a large supply droop when going from step 1 to step 2 and a similar recovery when going from step 2 to step 3.

Pattern A:

Step 1: Perform 1000 NOOPs.
Step 2: Read entire Array.
Step 3: Perform 1000 NOOPs.

Although multiplier 18 will recover at some point during step 2 and clock at the desired frequency, there will be a number of cycles at the beginning of step 2 which will NOT produce the desired test speed. In order to combat this problem, the pattern can be designed to allow the multiplier to recover, as follows.

Pattern B:

Step 1: Perform 1000 NOOPs.
Step 2: Perform X Read operations with No Compare.
Step 3: Read entire Array.
Step 4: Perform 1000 NOOPs.

Step 2 in the new pattern allows the DRAM to be clocked (but not tested) and to produce the correct current profile while the multiplier is recovering from the supply droop. After X reads (determined by characterization), the normal Read operations are performed with very accurate clock speeds due to the recovery of the multiplier. For this pattern, no recovery is necessary between step 3 and 4 due to the fact that step 4 is a NOOP pattern. If step 4 were a Write pattern, then an additional step (similar to step 2) may be required to inject “dummy” writes prior to the critical write step being performed.

The foregoing description of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

What is claimed is:

1. A system for testing a high speed integrated circuit using a low speed tester, comprising:
a built-in self test (BIST) engine coupled to the integrated circuit;
a clock multiplier adapted to derive a high speed clock signal from a clock signal supplied by the low speed tester, wherein the high speed clock signal drives the testing of the high speed integrated circuit; and
an edge shaper coupled to the clock multiplier and the BIST engine, the edge shaper configured to output a plurality of different shaped clock signals.

2. The system of claim 1, wherein the clock multiplier includes a register that stores a multiplier factor which determines a speed of the high speed clock signal, wherein the register is loadable by the BIST engine.

3. The system of claim 1, wherein the BIST engine includes logic that enables the clock multiplier and ensures that the high speed clock signal is locked into a steady state before the high speed clock signal is used for testing.

4. The system of claim 1, further comprising a multiplier test system that tests the clock multiplier by comparing a count in a utility counter with a preset maximum value and preset minimum value.

5. The system of claim 1, wherein the edge shaper includes a program register that stores information provided by the BIST engine which determines the shaped clock signal generated by the edge shaper.

6. The system of claim 1, further comprising a latch for turning the edge shaper on and off, wherein the latch is controlled by a signal from the BIST engine.

7. The system of claim 1, wherein the testing of the high speed integrated circuit comprises testing of a dynamic random access memory (DRAM).

8. An application specific integrated circuit (ASIC) device having a system for testing a high speed memory circuit using a low speed tester, the ASIC device comprising:
a built-in self test (BIST) engine;
a clock multiplier adapted to derive a high speed clock signal from a clock signal supplied by the low speed tester, wherein the high speed clock signal drives the testing of the high speed memory circuit; and
an edge shaper coupled to the clock multiplier and the BIST engine, the edge shaper configured to output a plurality of different shaped clock signals.

9. The ASIC device of claim 8, wherein the clock multiplier includes a register that stores a multiplier factor which determines a speed of the high speed clock signal, wherein the register is loadable by the BIST engine.

10. The ASIC device of claim 8, wherein the BIST engine includes logic that enables the clock multiplier, and ensures that the high speed clock signal is locked into a steady state before the high speed clock signal is used for testing the high speed memory circuit.

11. The ASIC device of claim 8, further comprising a multiplier test system that tests the clock multiplier by comparing a count in a utility counter with a preset maximum value and a preset minimum value.

12. The ASIC device of claim 8, wherein the edge shaper includes a program register that stores information provided by the BIST engine which determines the shaped clock signal generated by the edge shaper.

13. The ASIC device of claim 8, further comprising a latch for turning the edge shaper on and off, wherein the latch is controlled by a signal from the BIST engine.

14. The ASIC device of claim 8, wherein the high speed memory circuit comprises a dynamic random access memory (DRAM).

15. A method of testing a high speed memory circuit in an application specific integrated circuit (ASIC) device using a low speed clock, comprising:
providing a built-in self test (BIST) engine in the ASIC device;
providing a clock multiplier in the ASIC device;
providing an edge shaper in the ASIC device coupled to the clock multiplier and the BIST engine;
loading a multiplier factor from the BIST engine to the clock multiplier;
enabling the clock multiplier with an enable signal from the BIST engine to cause a high speed clock signal to be generated;
allowing a period of time to pass to allow the high speed clock signal to lock into a steady state; and
testing the high speed memory circuit with the high speed clock.

16. The method of claim 15, comprising the further steps of:
loading a value into a program register in the edge shaper from the BIST engine to determine a shaped clock signal to be generated by the edge shaper; and
enabling the edge shaper to generate a shaped high speed clock signal.

17. The method of claim 15, comprising the further steps of:
setting a minimum and maximum count value for a set of tester clocks; and
testing the clock multiplier by comparing a count in a utility counter with the maximum value and minimum count value.

18. The method of claim 15, wherein the high speed memory circuit comprises a dynamic random access memory (DRAM).

19. The method of claim 18, wherein the DRAM is tested using the steps of:
performing a series of non-operational (NOOP) DRAM cycles in order to initially lock the clock multiplier to a required frequency;
performing a series of read DRAM cycles to allow the clock multiplier to adjust to changing environment conditions; and
performing a series of read DRAM cycles to test the DRAM.

20. The method of claim 18, wherein the DRAM is tested using the steps of:
performing a series of non-operational (NOOP) DRAM cycles in order to initially lock the clock multiplier to a required frequency;
performing a series of write DRAM cycles to allow the clock multiplier to adjust to changing environment conditions; and
performing a series of write DRAM cycles to test the DRAM.
